(19) United States
(12) Patent Application Publication
(10) Pub. No.: US 2026/0096223 A1
(43) Pub. Date: Apr. 2, 2026

(54) ELECTROSTATIC DISCHARGE PROTECTION CIRCUIT

(71) Applicant: Winbond Electronics Corp., Taichung City (TW)

(72) Inventor: Jen-Hao Hsiao, Changhua (TW)

(73) Assignee: Winbond Electronics Corp., Taichung City (TW)

(21) Appl. No.: 19/019,392

(22) Filed: Jan. 13, 2025

(30) Foreign Application Priority Data
Sep. 30, 2024 (TW) 113137303

(51) Int. Cl. H10D 89/60

(52) U.S. Cl. CPC H10D 89/713

(57) ABSTRACT

An electrostatic discharge (ESD) protection circuit of this disclosure is provided, the ESD protection circuit is coupled between a first pad and a second pad. The ESD protection circuit includes a substrate having a first conductive type, a second conductive type transistor structure, a resistor structure, and a silicon controlled rectifier (SCR) structure. The transistor structure is disposed in the substrate and has a gate terminal. The resistor structure is disposed in the substrate and includes a first resistor. The gate terminal of the transistor structure is coupled to the second pad through the resistor structure. The SCR structure is disposed in the substrate and has a first terminal, a second terminal, and a third terminal. The first terminal, the second terminal, and the third terminal of the SCR structure are respectively coupled to the first pad, the second pad, and the gate terminal of the transistor structure.

### CROSS-REFERENCE TO RELATED APPLICATION

This application claims the priority benefit of Taiwan application serial no. 113137303, filed on Sep. 30, 2024. The entirety of the above-mentioned patent application is hereby incorporated by reference herein and made a part of this specification.

### BACKGROUND

### Technical Field

The disclosure relates to an electronic circuit, and in particular relates to an electrostatic discharge (ESD) protection circuit.

### Description of Related Art

In order to reduce the trigger voltage of a silicon controlled rectifier (SCR), in the conventional technology, a grounded-gated N-type metal-oxide-semiconductor (GGNMOS) transistor is coupled to the base terminal of the bipolar junction transistor (BJT) within the SCR structure. When an electrostatic discharge (ESD) pulse occurs, the snapback characteristic of the GGNMOS is utilized to induce current, thereby turning on (conducting) the SCR. In this way, the original high trigger voltage of the silicon controlled rectifier may be reduced to close to the snapback breakdown voltage of GGNMOS. However, this architecture still has issues of slow conduction speed of silicon controlled rectifier and insufficient electrostatic protection capability.

### SUMMARY

An electrostatic discharge protection circuit, which may speed up the conduction speed of the silicon controlled rectifier and improve the electrostatic protection capability, is provided in the disclosure. The electrostatic discharge protection circuit of the embodiment of the disclosure is coupled between a first pad and a second pad. The electrostatic discharge protection circuit includes a substrate, a second conductivity type transistor structure, a resistor structure, and a silicon controlled rectifier structure. The substrate has a first conductivity type. The second conductivity type transistor structure is disposed in the substrate and has a gate terminal. The resistor structure is disposed in the substrate and includes a first resistor. The gate terminal of the second conductivity type transistor structure is coupled to the second pad through the resistor structure. The silicon controlled rectifier structure is disposed in the substrate and has a first terminal, a second terminal, and a third terminal. The first terminal of the silicon controlled rectifier structure is coupled to the first pad, the second terminal of the silicon controlled rectifier structure is coupled to the second pad, and the third terminal of the silicon controlled rectifier structure is coupled to the gate terminal of the second conductivity type transistor structure.

In order to make the above-mentioned features and advantages of the disclosure comprehensible, embodiments accompanied with drawings are described in detail below.

### BRIEF DESCRIPTION OF THE DRAWINGS

FIG. 1 is a schematic diagram of an electrostatic discharge protection circuit according to an embodiment.

FIG. 2 is a cross-sectional schematic diagram of the electrostatic discharge protection circuit of the embodiment of FIG. 1.

### DETAILED DESCRIPTION OF DISCLOSED EMBODIMENTS

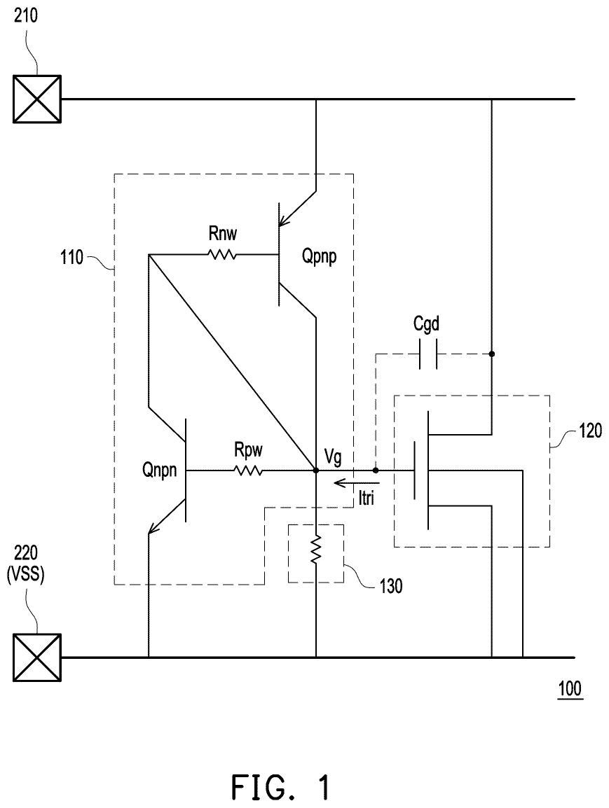

FIG. 1 is a schematic diagram of an electrostatic discharge protection circuit according to an embodiment. Referring to FIG. 1, the electrostatic discharge protection circuit 100 includes a silicon controlled rectifier 110, a first transistor 120, and a first resistor 130. The electrostatic discharge protection circuit 100 is coupled between the first pad 210 and the second pad 220. Under normal operating conditions, the voltage of the first pad 210 is greater than the voltage of the second pad 220. The second pad 220 is coupled to, for example, the system low voltage VSS.

The silicon controlled rectifier 110 has a first terminal, a second terminal, and a third terminal. The first terminal of the silicon controlled rectifier 110 is coupled to the first pad 210. The second terminal of the silicon controlled rectifier 110 is coupled to the second pad 220. The third terminal of the silicon controlled rectifier is coupled to the gate terminal of the transistor 120. When an electrostatic discharge pulse occurs at the first pad 210, the silicon controlled rectifier 110 may be turned on (conducted), so that the electrostatic discharge current may at least flow from the first pad 210 to the second pad 220 through the silicon controlled rectifier 110.

Specifically, the silicon controlled rectifier 110 includes a second transistor Qpnp, a third transistor Qnpn, a second resistor Rnw, and a third resistor Rpw. The second transistor Qpnp is, for example, a pnp-type bipolar junction transistor (BJT), and the third transistor Qnpn is, for example, an npn-type BJT. The emitter terminal of the second transistor Qpnp serves as the first terminal of the silicon controlled rectifier 110 and is coupled to the first pad 210. The collector terminal of the second transistor Qpnp serves as the third terminal of the silicon controlled rectifier 110 and is coupled to the gate terminal of the transistor 120. The base terminal of the second transistor Qpnp is coupled to one terminal of the second resistor Rnw. The other terminal of the second resistor Rnw is coupled to the collector terminal of the third transistor Qnpn and the collector terminal of the second transistor Qpnp. The emitter terminal of the third transistor Qnpn serves as the second terminal of the silicon controlled rectifier 110 and is coupled to the second pad 220. The base terminal of the third transistor Qnpn is coupled to one terminal of the third resistor Rpw. The other terminal of the third resistor Rpw is coupled to the collector terminal of the second transistor Qpnp.

When an electrostatic discharge pulse occurs at the first pad 210, the second transistor Qpnp and the third transistor Qnpn may be conducted, so that the electrostatic discharge current may at least flow from the first pad 210 to the second pad 220 through the second transistor Qpnp and the third transistor Qnpn.

The first transistor 120 has a first source/drain terminal, a second source/drain terminal, and a gate terminal. The first transistor 120 is, for example, an N-type metal-oxide-semiconductor (NMOS) transistor with a gate terminal connected to a resistor. The first source/drain terminal of the first transistor 120 is coupled to the first pad 210. The second source/drain terminal of the first transistor 120 is coupled to the second pad 220. The gate terminal of the first transistor 120 is coupled to the first terminal of the first resistor 130. A parasitic capacitance Cgd is formed between the first source/drain terminal and the gate terminal of the first transistor 120.

The first resistor 130 has a first terminal and a second terminal. The first terminal of the first resistor 130 is coupled to the gate terminal of the first transistor 120. The second terminal of the first resistor 130 is coupled to the second pad 210. That is, the gate terminal of the first transistor 120 is coupled to the second pad 220 through the first resistor 130. The resistance value of the first resistor 130 is greater than the resistance values of the second resistor Rnw and the third resistor Rpw.

When an electrostatic discharge pulse occurs at the first pad 210, the voltage Vg at the gate terminal of the first transistor 120 may be pulled up by the parasitic capacitance Cgd to generate the trigger current Itri. Since the resistance value of the first resistor 130 is greater than the resistance values of the second resistor Rnw and the third resistor Rpw, the charge at the gate terminal of the first transistor 120 flows into the silicon controlled rectifier 110 to generate the trigger current Itri. The trigger current Itri may speed up the conduction speed of the silicon controlled rectifier and reduce the trigger voltage of the silicon controlled rectifier 110. Therefore, the silicon controlled rectifier 110 may quickly provide a discharge path, so that the electrostatic discharge current may flow from the first pad 210 to the second pad 220 through the conducted silicon controlled rectifier 110.

On the other hand, since the voltage Vg at the gate terminal of the first transistor 120 is pulled up by the parasitic capacitance Cgd, when the voltage Vg at the gate terminal is greater than the threshold voltage of the first transistor 120, the first transistor 120 will be conducted. Therefore, the first transistor 120 may provide another discharge path, so that the electrostatic discharge current may flow from the first pad 210 to the second pad 220 through the conducted first transistor 120.

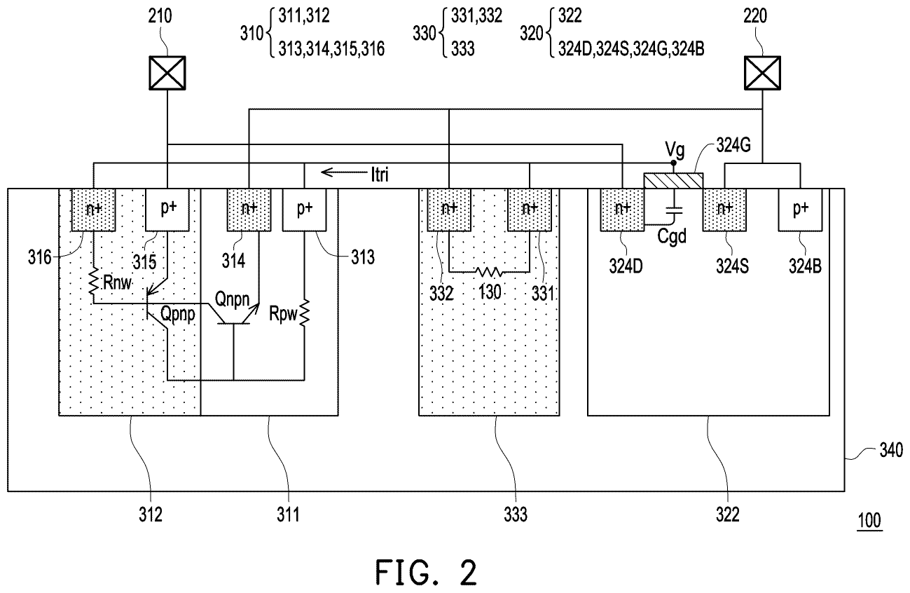

FIG. 2 is a cross-sectional schematic diagram of the electrostatic discharge protection circuit of the embodiment of FIG. 1. Referring to FIG. 1 and FIG. 2, the electrostatic discharge protection circuit 100 includes a P-type (first conductivity type) substrate 340, an N-type (second conductivity type) transistor structure 320, a resistor structure 330, and a silicon controlled rectifier structure 310. The N-type transistor structure 320, the resistor structure 330, and the silicon controlled rectifier structure 310 are disposed in the substrate 340.

The N-type transistor structure 320 corresponds to the first transistor 120 of FIG. 1. The N-type transistor structure 320 includes a P-type well (first well) 322, a first source/drain region 324D, a second source/drain region 324S, a base region 324B, and a gate electrode 324G. The first source/drain region 324D, the second source/drain region 324S, the base region 324B, and the gate electrode 324G respectively serve as the first source/drain terminal, the second source/drain terminal, the base terminal, and the gate terminal of the first transistor 120. The P-type well 322 is disposed in the substrate 340. The first source/drain region 324D, the second source/drain region 324S, and the base region 324B are disposed in the P-type well 322. The gate electrode is disposed on the P-type well 322. The first source/drain region 324D and the second source/drain region 324S are N-type heavily doped regions, and the base region 324B is a P-type heavily doped region. The gate electrode is a metal material. The first source/drain region 324D is coupled to the first pad 210. The second source/drain region 324S and the base region 324B are coupled to the second pad 220. A parasitic capacitance Cgd is formed between the first source/drain region 324D and the gate electrode 324G.

The resistor structure 330 corresponds to the first resistor 130 of FIG. 1. The resistor structure 330 includes an N-type well (second well) 333, a first heavily doped region 331, and a second heavily doped region 332. The N-type well 333 is disposed in the substrate 340. The N-type well 333 is separated from the P-type well 322. The first heavily doped region 331 and the second heavily doped region 332 are N-type heavily doped regions and are disposed in the N-type well 333. The first heavily doped region 331 is coupled to the gate electrode 324G, and the second heavily doped region 332 is coupled to the second pad 220.

The silicon controlled rectifier structure 310 corresponds to the silicon controlled rectifier 110 of FIG. 1. The silicon controlled rectifier structure 310 includes a P-type well (third well) 311, an N-type well (fourth well) 312, a third heavily doped region 313, a fourth heavily doped region 314, a fifth heavily doped region 315, and a sixth heavily doped region 316. The P-type well 311 and the N-type well 312 are adjacent and disposed in the substrate 340. The P-type well 311 is separated from the P-type well 322 and the N-type well 333. The N-type well 312 is also separated from the P-type well 322 and the N-type well 333. The third heavily doped region 313 and the fourth heavily doped region 314 are disposed in the P-type well 311. The fifth heavily doped region 315 and the sixth heavily doped region 316 are disposed in the N-type well 312. The third heavily doped region 313 and the fifth heavily doped region 315 are P-type heavily doped regions. The fourth heavily doped region 314 and the sixth heavily doped region 316 are N-type heavily doped regions. The third heavily doped region 313 and the sixth heavily doped region 316 are coupled to the gate electrode 324G. The fourth heavily doped region 314 is coupled to the second pad 220. The fifth heavily doped region 315 is coupled to the first pad 210.

To sum up, in the embodiments of the disclosure, when an electrostatic discharge pulse occurs, the gate voltage of the first transistor may be pulled up by the parasitic capacitance to generate a trigger current and turn on (conduct) the first transistor. This trigger current speeds up the conduction speed of the silicon controlled rectifier to quickly provide a discharge path. In addition, since the first transistor may also provide a discharge path, the electrostatic protection capability may be further improved.

Although the disclosure has been described in detail with reference to the above embodiments, they are not intended to limit the disclosure. Those skilled in the art should understand that it is possible to make changes and modifications without departing from the spirit and scope of the disclosure. Therefore, the protection scope of the disclosure shall be defined by the following claims.

What is claimed is:

1. An electrostatic discharge protection circuit, coupled between a first pad and a second pad, the electrostatic discharge protection circuit comprising:
a substrate, having a first conductivity type;
a second conductivity type transistor structure, disposed in the substrate and having a gate terminal;
a resistor structure, disposed in the substrate and comprising a first resistor, wherein the gate terminal of the second conductivity type transistor structure is coupled to the second pad through the resistor structure; and
a silicon controlled rectifier structure, disposed in the substrate and having a first terminal, a second terminal, and a third terminal, wherein the first terminal of the silicon controlled rectifier structure is coupled to the first pad, the second terminal of the silicon controlled rectifier structure is coupled to the second pad, and the third terminal of the silicon controlled rectifier structure is coupled to the gate terminal of the second conductivity type transistor structure.

2. The electrostatic discharge protection circuit according to claim 1, wherein the silicon controlled rectifier structure further comprises a third resistor.

3. The electrostatic discharge protection circuit according to claim 2, wherein a resistance value of the first resistor is greater than a resistance value of the third resistor.

4. The electrostatic discharge protection circuit according to claim 1, wherein the second conductive type transistor structure further has a first source/drain terminal, a second source/drain terminal and a base terminal.

5. The electrostatic discharge protection circuit according to claim 4, wherein a parasitic capacitance is formed between the first source/drain terminal and the gate terminal.

6. The electrostatic discharge protection circuit according to claim 4, wherein the first source/drain terminal is coupled to the first pad, and the second source/drain terminal and the base terminal are coupled to the second pad.

7. The electrostatic discharge protection circuit according to claim 1, wherein the resistor structure has a first terminal and a second terminal, the first terminal of the resistor structure is coupled to the gate terminal of the second conductive type transistor structure, and the second terminal of the resistor structure is coupled to the second pad.

8. The electrostatic discharge protection circuit according to claim 1, wherein the second conductivity type transistor structure comprises:
a first well, disposed in the substrate;
a first source/drain region, disposed in the first well, and coupled to the first pad;
a second source/drain region, disposed in the first well, and coupled to the second pad;
a base region, disposed in the first well, and coupled to the second pad; and
a gate electrode, disposed on the first well.

9. The electrostatic discharge protection circuit according to claim 8, wherein the first well and the base region have the first conductivity type, and the second source/drain region and the second source/drain region have the second conductivity type.

10. The electrostatic discharge protection circuit according to claim 8, wherein the resistor structure comprises:
a second well, disposed in the substrate;
a first heavily doped region, disposed in the second well, and coupled to the gate electrode; and
a second heavily doped region, disposed in the second well, and coupled to the second pad.

11. The electrostatic discharge protection circuit according to claim 10, wherein the second well, the first heavily doped region, and the second heavily doped region have the second conductivity type.

12. The electrostatic discharge protection circuit according to claim 7, wherein the silicon controlled rectifier structure comprises:
a third well, disposed in the substrate;
a third heavily doped region, disposed in the third well, and coupled to the gate electrode;
a fourth heavily doped region, disposed in the third well, and coupled to the second pad;
a fourth well, disposed in the substrate;
a fifth heavily doped region, disposed in the fourth well, and coupled to the first pad; and
a sixth heavily doped region, disposed in the fourth well, and coupled to the gate electrode.

13. The electrostatic discharge protection circuit according to claim 12, wherein the third well and the third heavily doped region have the first conductivity type, and the fourth heavily doped region has the second conductivity type.

14. The electrostatic discharge protection circuit according to claim 12, wherein the fifth heavily doped region has the first conductivity type, and the fourth well and the sixth heavily doped region have the second conductivity type.

15. The electrostatic discharge protection circuit according to claim 12, wherein the second well is separated from the first well.

16. The electrostatic discharge protection circuit according to claim 12, wherein the fourth well is adjacent to the third well and separated from the first well and the second well.

17. The electrostatic discharge protection circuit according to claim 1, wherein when an electrostatic discharge pulse occurs at the first pad, a voltage at the gate terminal is pulled up through a parasitic capacitance to generate a trigger current.

18. The electrostatic discharge protection circuit according to claim 17, wherein the trigger current is configured to speed up conduction speed of a silicon controlled rectifier.

19. The electrostatic discharge protection circuit according to claim 17, wherein when the voltage at the gate terminal is greater than a threshold voltage of a second conductive type transistor, the second conductive type transistor is conducted.

20. The electrostatic discharge protection circuit according to claim 19, wherein an electrostatic discharge current flows from the first pad to the second pad through the silicon controlled rectifier that is conducted and the second conductive type transistor that is conducted.
